(19) United States
(12) Patent Application Publication
(10) Pub. No.: US 2024/0112982 A1
(43) Pub. Date: Apr. 4, 2024

(54) SEMICONDUCTOR DEVICE AND METHOD FOR MANUFACTURING SEMICONDUCTOR DEVICE

(71) Applicant: SONY SEMICONDUCTOR SOLUTIONS CORPORATION, Kanagawa (JP)

(72) Inventor: Hirofumi MAKINO, Kanagawa (JP)

(73) Assignee: SONY SEMICONDUCTOR SOLUTIONS CORPORATION, Kanagawa (JP)

(21) Appl. No.: 18/264,725

(22) PCT Filed: Jan. 13, 2022
(86) PCT No.: PCT/JP2022/000909

§ 371 Date: Aug. 8, 2023

(30) Foreign Application Priority Data
Feb. 19, 2021 (JP) 2021-025070

(51) Int. Cl. H01L 23/427; H01L 23/00; H01L 23/053; H01L 23/29; H01L 23/373; H01L 27/146

(52) U.S. Cl. CPC H01L 23/427; H01L 23/053; H01L 23/293; H01L 23/3737; H01L 24/48; H01L 27/14618; H01L 24/32; H01L 24/73; H01L 2224/32225; H01L 2224/48227; H01L 2224/73265

(57) ABSTRACT

A semiconductor device according to the present technology includes a semiconductor chip, and a wiring board portion having the semiconductor chip mounted thereon and having an external connection terminal for establishing electrical connection to the outside, the external connection terminal being formed on its back surface which is a surface opposite to its front surface which is a surface on which the semiconductor chip is mounted, in which the semiconductor chip is connected to a terminal formed on the front surface of the wiring board portion through a bonding wire to be wire-bonded to the wiring board portion, and a heat dissipation member is disposed between the bonding wire and the wiring board portion.

### TECHNICAL FIELD

The present technology relates to semiconductor devices and methods for manufacturing the same. Particularly, the present technology relates to semiconductor devices including a semiconductor chip, and a wiring board portion having the semiconductor chip mounted thereon and having an external connection terminal for establishing electrical connection to the outside, the external connection terminal being formed on its back surface which is a surface opposite to its front surface which is a surface on which the semiconductor chip is mounted, in which the semiconductor chip is connected to a terminal formed on the front surface of the wiring board portion through a bonding wire to be wire-bonded to the wiring board portion. Further, particularly, the present technology relates to methods for manufacturing the same.

### BACKGROUND ART

For example, as semiconductor devices such as solid-state image pickup elements (image sensors), there are semiconductor devices of a type which includes a semiconductor chip having various electronic circuit components such as transistors which are formed thereon, such that the semiconductor chip is disposed in a box-shaped casing constituted by a wiring board portion, a frame portion, and a lid portion.

The aforementioned wiring board portion is a portion provided with wiring for enabling signal transmission between the semiconductor chip and an external device. For example, the semiconductor chip is wire-bonded to a terminal formed on the front surface of the wiring board portion, namely, the surface thereof on which the semiconductor chip is mounted, so that the semiconductor chip is electrically connected to the wiring board portion.

In recent years, various semiconductor devices have been required to have high functionality, high processing speeds, and the like, which tends to increase the power consumption in semiconductor chips and, also, tends to increase heat generation therein. For example, semiconductor devices as solid-state image pickup elements have tended to increase heat generation from semiconductor chips therein, since such semiconductor devices have been required to have larger numbers of pixels, higher frame rates, and the like.

Due to the increase of heat generation from semiconductor chips, the wiring board portions or the semiconductor chips themselves may suffer deformation and the like, which may make it impossible to exert desired functions. For coping therewith, such semiconductor devices have been provided with cooling configurations.

As conventional techniques for cooling semiconductor devices, for example, there have been a technique which disposes a cooling block at a portion on the back side of a semiconductor chip (refer to Patent Document 1 cited below, for example), and a technique which disposes a Peltier element (refer to Patent Document 2 cited below, for example).

### CITATION LIST

### Patent Document

Patent Document 1: Japanese Patent Application Laid-Open No. 2013-98853
Patent Document 2: Japanese Patent Application Laid-Open No. 2011-234127

### SUMMARY OF THE INVENTION

### Problems to be Solved by the Invention

However, with the aforementioned conventional techniques, it is necessary to secure a space for disposing a component for cooling, such as a cooling block or a Peltier element, at a portion on the back side of a semiconductor chip, which may cause the semiconductor device to have a larger size.

The present technology was made in view of the aforementioned circumstances, and aims at preventing a semiconductor device from having a larger size for the purpose of cooling.

### Solutions to Problems

A semiconductor device according to the present technology includes:
a semiconductor chip, and a wiring board portion having the semiconductor chip mounted thereon and having an external connection terminal for establishing electrical connection to the outside, the external connection terminal being formed on its back surface which is a surface opposite to its front surface which is a surface on which the semiconductor chip is mounted, in which the semiconductor chip is connected to a terminal formed on the front surface of the wiring board portion through a bonding wire to be wire-bonded to the wiring board portion, and a heat dissipation member is disposed between the bonding wire and the wiring board portion.

The heat dissipation member means a member which forms at least a part of a heat dissipation path for cooling heat generated in the semiconductor chip. According to the aforementioned configuration, the heat dissipation member is disposed near the semiconductor chip which forms a heat source. Further, in this case, the semiconductor device can be cooled by the heat dissipation member disposed in a dead space below the bonding wire.

In the semiconductor device according to the aforementioned present technology, the heat dissipation member can be at least partially in contact with a side surface of the semiconductor chip.

This improves the efficiency of heat conduction from the semiconductor chip to the heat dissipation member.

In the semiconductor device according to the aforementioned present technology, the heat dissipation member can be constituted by a heat pipe.

Here, the heat pipe means a heat conductor which includes a sealed container enclosing a refrigerant (for example, a liquid such as water), and also includes a capillary structure (wick) provided on an inner wall thereof.

The semiconductor device according to the aforementioned present technology may include a frame portion which protrudes from the wiring board portion in the same side as the side in which the semiconductor chip is mounted and which surrounds the side portion of the semiconductor chip, in which the frame portion may cover the bonding wire.

Thus, an inner peripheral portion of the frame portion extends up to an outer edge portion of the semiconductor chip.

The semiconductor device according to the aforementioned present technology may include a frame portion which protrudes from the wiring board portion in the same side as the side in which the semiconductor chip is mounted and which is provided outside the semiconductor chip to surround the side portion of the semiconductor chip, and, in the frame portion, there is disposed an in-frame heat dissipation member which is a heat dissipation member different from the aforementioned heat dissipation member.

The wiring board portion also functions as a heat dissipation path for heat generated in the semiconductor chip and, therefore, heat from the semiconductor chip can be also dissipated through the in-frame heat dissipation member (by way of the wiring board portion and the frame portion).

In the semiconductor device according to the aforementioned present technology, the heat dissipation member can be at least partially embedded in a groove formed in the front surface of the wiring board portion.

Since the heat dissipation member is at least partially embedded in the groove formed in the wiring board portion as described above, it is possible to use the heat dissipation member having a larger cross-sectional area within the limited space below the bonding wire.

In the semiconductor device according to the aforementioned present technology, the heat dissipation member can be bonded to the side surface of the semiconductor chip through a thermally conductive resin.

In a case where the heat dissipation member has a cross-sectional shape which is a shape other than a rectangular shape or the like, such as a case where a heat pipe is used as the heat dissipation member, it is difficult to bring the heat dissipation member evenly into intimate contact with the side surface of the semiconductor chip. For coping therewith, the heat dissipation member is bonded to the side surface of the semiconductor chip using the thermally conductive resin, in order to increase the degree of thermal intimate contact between the heat dissipation member and the semiconductor chip.

In the semiconductor device according to the aforementioned present technology, the semiconductor chip is formed to have a substantially rectangular plate shape, and the heat dissipation member is in contact with all of the four side surfaces of the semiconductor chip.

This enables guiding heat generated in the semiconductor chip to the heat dissipation member, through all of the four side surfaces of the semiconductor chip.

In the semiconductor device according to the aforementioned present technology, a communication path from the heat dissipation member to a heat release portion may be formed on the front surface of the wiring board portion.

This can eliminate the necessity of perforating the wiring board portion in connecting the heat dissipation member and the communication path to each other.

In the semiconductor device according to the aforementioned present technology, a communication path from the heat dissipation member to a heat release portion may be formed on the back surface of the wiring board portion.

Therefore, in a case where a molded component as the frame portion is attached to the wiring board portion, it is possible to eliminate the necessity of machining the frame portion (forming a groove for passing the communication path therethrough).

The semiconductor device according to the aforementioned present technology may include a frame portion which protrudes from the wiring board portion in the same side as the side in which the semiconductor chip is mounted and which surrounds the side portion of the semiconductor chip, and a transparent resin with which the space surrounded by the frame portion is filled.

Namely, the semiconductor device has a so-called caviless structure (cavity-less structure) which does not employ a lid portion including a glass or the like for sealing the region surrounded by the frame portion, from above the frame portion. In this case, the semiconductor chip is covered with the transparent resin, in the space surrounded by the frame portion.

The semiconductor device according to the aforementioned present technology can be structured to be a semiconductor device as a solid-state image pickup element.

Therefore, it is possible to improve the efficiency of cooling the semiconductor device as a solid-state image pickup element.

A method for manufacturing a semiconductor device according to the present technology is a method for manufacturing a semiconductor device including a semiconductor chip, and a wiring board portion having the semiconductor chip mounted thereon and having an external connection terminal for establishing electrical connection to the outside, the external connection terminal being formed on its back surface which is a surface opposite to its front surface which is a surface on which the semiconductor chip is mounted, and the semiconductor chip being connected to a terminal formed on the front surface of the wiring board portion through a bonding wire to be wire-bonded to the wiring board portion, in which the method includes at least a process for disposing a heat dissipation member between the bonding wire and the wiring board portion.

With this manufacturing method, it is possible to manufacture the semiconductor devices according to the aforementioned present technology.

### BRIEF DESCRIPTION OF DRAWINGS

FIG. 1 is a schematic longitudinal cross-sectional view of a semiconductor device according to a first embodiment of the present technology.

FIG. 2 is a schematic plan view of the semiconductor device according to the first embodiment of the present technology.

FIG. 3 is a schematic longitudinal cross-sectional view of a semiconductor device as a modification example of the first embodiment.

FIG. 4 is a schematic plan view of the semiconductor device as the modification example of the first embodiment.

FIG. 5 is an explanatory view of an example of a method for manufacturing the semiconductor device according to the first embodiment.

FIG. 6 is an explanatory view of a modification example of the position at which communication paths are formed.

FIG. 7 is a schematic longitudinal cross-sectional view of a semiconductor device according to a second embodiment.

FIG. 8 is a schematic plan view of the semiconductor device according to the second embodiment.

FIG. 9 is an explanatory view of an example of a method for manufacturing the semiconductor device according to the second embodiment.

FIG. 10 is a schematic longitudinal cross-sectional view of a semiconductor device according to a third embodiment.

FIG. 11 is a schematic plan view of the semiconductor device according to the third embodiment.

FIG. 12 is an explanatory view of an example of a method for manufacturing the semiconductor device according to the third embodiment.

FIG. 13 is a schematic longitudinal cross-sectional view of a semiconductor device as a first example of a fourth embodiment.

FIG. 14 is an explanatory view of an example of a method for manufacturing the semiconductor device as the first example of the fourth embodiment.

FIG. 15 is a schematic longitudinal cross-sectional view of a semiconductor device as a second example of the fourth embodiment.

FIG. 16 is a schematic longitudinal cross-sectional view of a semiconductor device as a third example of the fourth embodiment.

### MODE FOR CARRYING OUT THE INVENTION

Hereinafter, embodiments will be described in the following order.
1. First Embodiment
(1-1. Example of the Configuration of Semiconductor Device)
(1-2. Example of Method for Manufacturing Semiconductor Device)
2. Second Embodiment
3. Third Embodiment
4. Fourth Embodiment
<5. Modification Examples>
<6. Conclusion of Embodiments>
<7. Present Technology>

### 1. First Embodiment

### 1-1. Example of the Configuration of Semiconductor Device

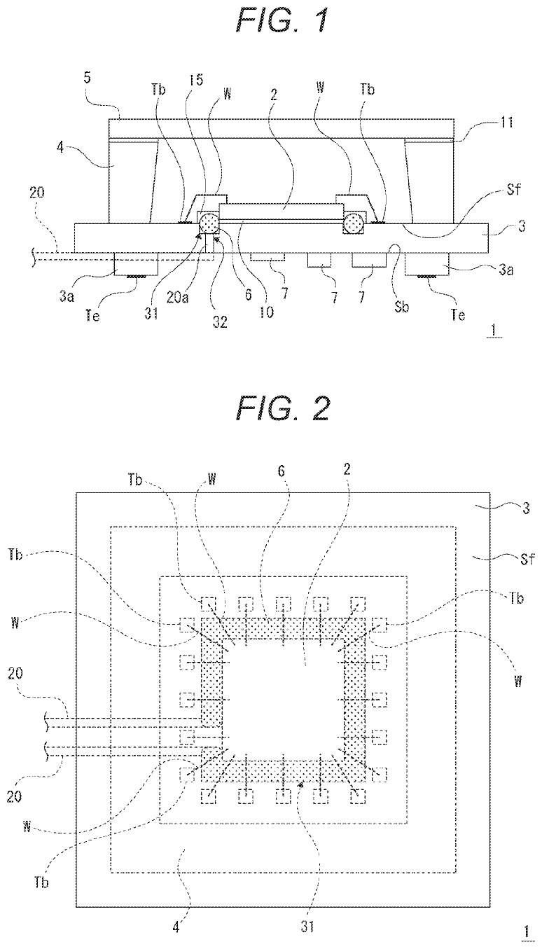

With reference to FIGS. 1 and 2, a semiconductor device 1 according to a first embodiment will be described.

FIG. 1 is a schematic longitudinal cross-sectional view of the semiconductor device 1, and FIG. 2 is a schematic plan view of the semiconductor device 1. Incidentally, here, the longitudinal direction refers to a direction parallel to the thickwise direction of a semiconductor chip 2 included in the semiconductor device 1.

The semiconductor device 1 includes at least: the semiconductor chip 2 provided with various electronic circuit components such as transistors; a wiring board portion 3 provided with wiring for enabling signal transmission between the semiconductor chip 2 and an external device (a device external to the semiconductor device 1); a frame portion 4 having a frame shape and forming a side wall portion of the semiconductor device 1; a lid portion 5 for sealing a region surrounded by the frame portion 4; and a heat dissipation member 6 which forms at least a part of a heat dissipation path for cooling heat generated in the semiconductor chip 2.

Here, the wiring board portion 3 can be also referred to as an interposer board.

In the present example, the semiconductor device 1 is configured to be a solid-state image pickup element (image sensor) such as a charge coupled device (CCD) sensor or a complementary metal oxide semiconductor (CMOS) sensor.

In the present example, the semiconductor chip 2 is formed to be a light receiving semiconductor chip for obtaining a captured image, and includes a plurality of pixels each having a photoelectric conversion element for performing photoelectric conversion, such that the pixels are two-dimensionally arranged therein. Further, for each pixel, the semiconductor chip 2 is provided with a pixel circuit for reading out an accumulated charge in the photoelectric conversion element.

The semiconductor chip 2 has a rectangular plate-like outer shape.

The semiconductor chip 2 is mounted on the wiring board portion 3. Hereinafter, the surface of the wiring board portion 3 on which the semiconductor chip 2 is mounted will be referred to as a front surface Sf, and the surface thereof opposite to the front surface Sf will be referred to as a back surface Sb.

The wiring board portion 3 includes insulating layers, and wiring layers including electric wirings formed therein in a predetermined pattern, such that the insulating layers and the wiring layers are alternately laminated. Vias are formed in the insulating layers, and the electric wirings in the wiring layers are electrically connected to each other through the vias.

A plurality of terminals Tb for electrically connecting the wiring board portion 3 to the semiconductor chip 2 is formed on the front surface Sf of the wiring board portion 3.

The semiconductor chip 2 is secured to the front surface Sf of the wiring board portion 3 through a chip adhesive 10 such as a die bond. Further, to the respective terminals Tb formed on the front surface Sf of the wiring board portion 3, corresponding terminals on the semiconductor chip 2 are electrically connected, through bonding wires W. Namely, the semiconductor chip 2 is electrically (and physically) connected to the wiring board portion 3 through the wire bonding.

In the present embodiment, on the back surface Sb of the wiring board portion 3, there is formed a protrusion 3a protruding in the side opposite to the side in which the semiconductor chip 2 is mounted. In the present example, the protrusion 3a is formed to have a substantially rectangular frame shape in a plan view.

On a tip end portion of the protrusion 3a in the protruding direction, there is formed a plurality of external connection terminals Te for establishing electrical connection with a device external to the semiconductor device 1. Through the external connection terminals Te, signals can be transmitted between the external device and the semiconductor chip 2.

In the present example, electronic components 7 are mounted on the back surface Sb of the wiring board portion 3, in the portion thereof which is surrounded by the protrusion 3a. Incidentally, the “electronic components” described herein broadly means semiconductor chips other than the semiconductor chip 2, other semiconductor devices having package structures, electronic components as passive components for the semiconductor chip 2, and the like. FIG. 1 illustrates a plurality of such “electronic components” which are mounted thereon, and the respective electronic components are denoted by the same reference sign, which is a reference sign of “7”. However, in a case where a plurality of electronic components is mounted thereon, the respective electronic components may be components having the same function or components having different functions. Also, the respective electronic components may be different from one another in shape, size, and the like.

The frame portion 4 protrudes from the wiring board portion 3 in the same side as the side in which the semiconductor chip 2 is mounted, and the frame portion 4 surrounds the side portions of the semiconductor chip. Specifically, the frame portion 4 in the present example is provided on the front surface Sf of the wiring board portion 3, outside the semiconductor chip 2.

The thickness of the frame portion 4, in other words, the entire height of the frame portion 4 is larger than the heights of the bonding wires W (the heights thereof from the wiring board portion 3). This enables the frame portion 4 to protect the components such as the semiconductor chip 2 and the bonding wires W mounted on the front surface Sf of the wiring board portion 3, at the side portions.

A lid portion 5 has a substantially rectangular plate shape, and is disposed on the frame portion 4 so as to cover the entire space surrounded by the frame portion 4 above the front surface Sf of the wiring board portion 3. The lid portion 5 is bonded to the frame portion 4 through a lid-portion adhesive 11.

The lid portion 5 seals the entire space surrounded by the frame portion 4, in order to protect the semiconductor chip 2 from an external environment such as water, humidity, and external forces. Specifically, in the present example, the space surrounded by the frame portion 4 is filled with dry air or nitrogen and then is sealed by the lid portion 5, or is evacuated and then is sealed by the lid portion 5 (namely, vacuum-sealed).

In the semiconductor device 1 in the present example, which is a solid-state image pickup element, the lid portion 5 includes a transparent substrate including a glass or the like, for example.

The heat dissipation member 6 is disposed between the bonding wires W and the wiring board portion 3. Namely, the heat dissipation member 6 is disposed at a position below the bonding wires W, on the wiring board portion 3.

In the present example, a heat pipe is used as the heat dissipation member 6. Here, the heat pipe means a heat conductor which includes a sealed container enclosing (for example, vacuum-enclosing) a refrigerant (for example, a liquid such as water), and also includes a capillary structure (wick) provided on an inner wall thereof.

As the heat pipe, it is possible to employ a metal pipe having excellent thermal conductivity, such as a pipe including copper, aluminum, or the like, for example.

In the present example, the heat dissipation member 6 is formed so as to surround and substantially go around the side surfaces of the semiconductor chip 2. One end portion and the other end portion of the heat dissipation member 6, which surrounds and substantially goes around the side surfaces of the semiconductor chip 2 as described above, are connected to each other through communication paths 20. Although not illustrated, specifically, ahead of the communication paths 20, there is formed a heat release portion for cooling (liquefying) the refrigerant (having been vaporized by being heated) in the heat pipe, and the refrigerant can be circulated (looped) through the heat dissipation member 6, the communication paths 20, and the heat release portion. Here, the communication paths 20 and the heat release portion also have a heat pipe structure. It can be said that the communication paths 20 and the heat release portion constitute a part of the heat pipe.

The heat pipe is internally made to be in a highly decompressed state, which tends to easily evaporate the liquid as a refrigerant. When a part of the heat pipe is heated, the liquid as the refrigerant becomes a vapor flow and moves to an unheated portion having a lower temperature (the aforementioned heat release portion). The moved vapor comes into contact with the inner wall of the heat release portion and returns to liquid while transferring heat thereto. This is referred to as heat release due to latent heat of condensation. The refrigerant having returned to the liquid passes along the capillary structure and returns to the original position, and is heated again. Then, the refrigerant is repeatedly evaporated, moved, and condensed, as described above, thereby performing heat transportation. According to this principle, it is possible to cool a target heat source.

Here, the heat dissipation member 6 is at least partially in contact with the side surfaces of the semiconductor chip 2. Specifically, the heat dissipation member 6 in the present example is in contact with all of the four side surfaces of the semiconductor chip 2.

Furthermore, in the present example, the heat dissipation member 6 is at least partially embedded in a groove 31 formed in the front surface Sf of the wiring board portion 3.

The groove 31 is formed so as to surround and go around the periphery of the semiconductor chip 2 in a plan view, similarly to the heat dissipation member 6, and, thus, the heat dissipation member 6 is entirely embedded therein in a plan view.

The groove 31 is formed to have a depth smaller than the total height of the heat dissipation member 6, so that a part of the heat dissipation member 6 protrudes from the groove 31, and this protruding part of the heat dissipation member 6 is allowed to partially come in contact with the side surfaces of the semiconductor chip 2.

Since the heat dissipation member 6 is at least partially embedded in the groove 31, it is possible to use the heat dissipation member 6 having a larger cross-sectional area within the limited space below the bonding wires W.

For example, as an example of a specific numerical value, the clearance from the bonding wires W to the wiring board portion 3 in the heightwise direction is about 120 μm to 150 μm. On the other hand, in a case of using a heat pipe as the heat dissipation member 6, in a current condition, the heat pipe has a thickness of 150 μm or more, for example. Therefore, in the current condition, it is difficult to arrange the heat pipe within the space below the bonding wires W without machining the wiring board portion 3, and it is effective to provide the groove 31 as described above.

Further, in the present example, the heat dissipation member 6 is bonded to the side surfaces of the semiconductor chip 2 through a thermally conductive resin 15.

As the thermally conductive resin 15, for example, it is desirable to use a thermosetting resin having a relatively higher thermal conductivity. Examples of such a thermosetting resin include a resin paste for die bonding, a resin paste containing a silver paste. Specific examples thereof include ATROX (registered trademark) D800HT series manufactured by Techno Alpha Co., Ltd.

In a case where the heat dissipation member 6 has a cross-sectional shape which is a shape other than a rectangular shape or the like, such as a case where a heat pipe is used as the heat dissipation member 6 as in the present example, it is difficult to bring the heat dissipation member 6 evenly into intimate contact with the side surfaces of the semiconductor chip 2. For coping therewith, the heat dissipation member 6 is bonded to the side surfaces of the semiconductor chip 2 using the thermally conductive resin 15, in order to increase the degree of thermal intimate contact between the heat dissipation member 6 and the semiconductor chip 2.

Incidentally, in order to increase the degree of thermal intimate contact between the heat dissipation member 6 and the semiconductor chip 2, it is not essential to use a material having adhesiveness. As an example, it is also conceivable to apply a heat release paste such as Thermal Interface Materials (TIM) manufactured by Cosmo Oil Lubricants, to the gap between the heat dissipation member 6 and the semiconductor chip 2, in such a way as to fill the gap therewith.

Here, in the present example, the communication paths 20 from the heat dissipation member 6 to the aforementioned heat release portion are formed on the back surface Sb of the wiring board portion 3.

Specifically, in this case, parts 20a (see FIG. 1) of the communication paths 20 are disposed in grooves 32 penetrating the wiring board portion 3 in the thickwise direction, and are connected to the end portions of the heat dissipation member 6 partially embedded in the groove 31. In the present example, there are two communication paths 20, the part 20a of one communication path 20 is connected to one end portion of the heat dissipation member 6, and the part 20a of the other communication path 20 is connected to the other end portion of the heat dissipation member 6.

By forming the communication paths 20 on the back surface Sb of the wiring board portion 3 as described above, in a case where a molded component as the frame portion 4 is attached to the wiring board portion 3, it is possible to eliminate the necessity of machining the frame portion 4 (forming grooves 32 for passing the communication paths 20 therethrough).

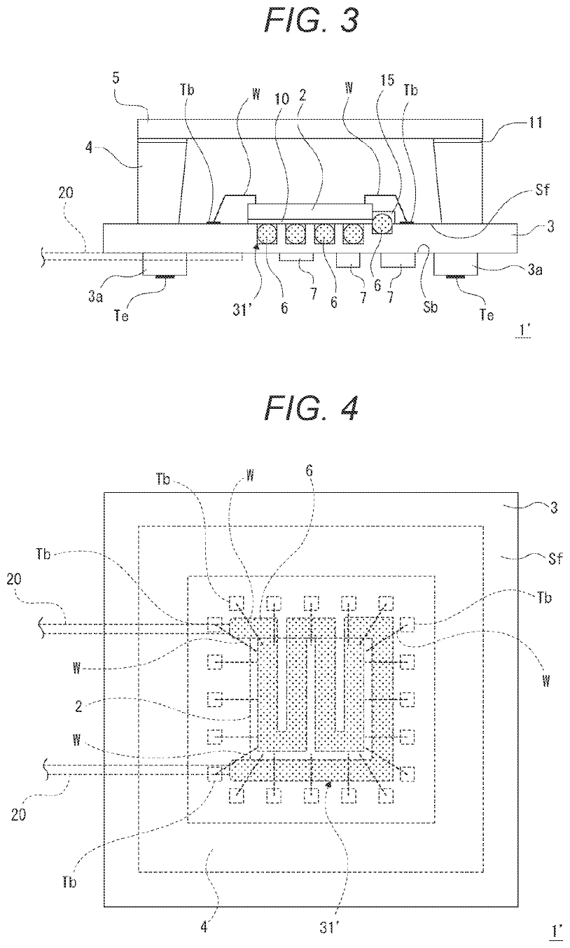

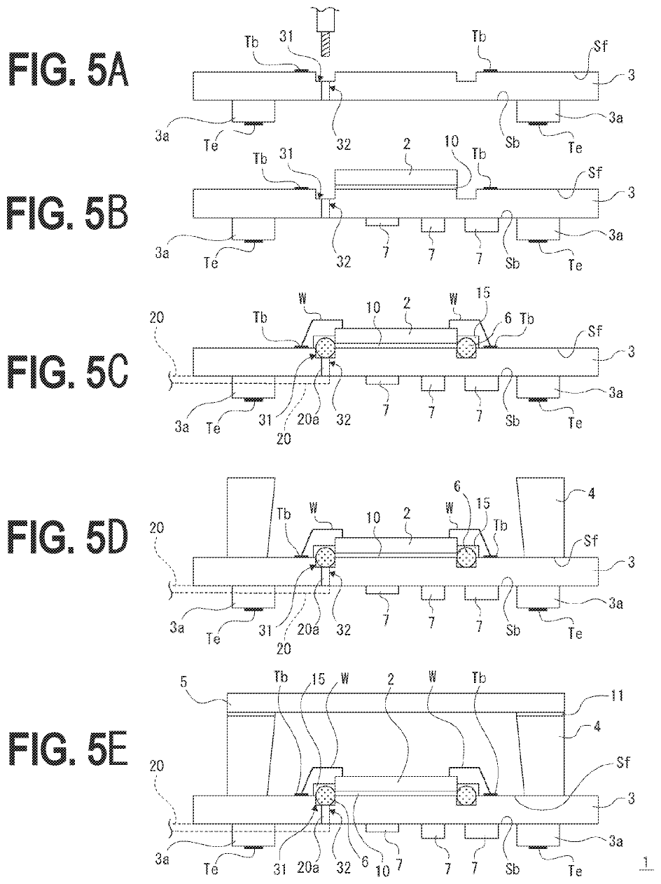

FIGS. 3 and 4 are views for explaining the configuration of a semiconductor device 1′ as a modification example of the first embodiment. FIG. 3 is a schematic longitudinal cross-sectional view of the semiconductor device 1′, and FIG. 4 is a schematic plan view of the semiconductor device 1′.

Incidentally, in the following description, portions similar to the portions described previously will be denoted by the same reference signs, and will not be described.

The semiconductor device 1′ differs from the semiconductor device 1 in the path layout of a heat dissipation member 6.

In the semiconductor device 1′, a part of the heat dissipation member 6 is disposed at a position beneath a semiconductor chip 2 inside a wiring board portion 3. Specifically, in the present example, the heat dissipation member 6 is formed to have a plurality of folded portions beneath the semiconductor chip 2. Here, the term “a folded portion” means a portion having a fold in the planar direction of the wiring board portion 3.

Further, in the present example, the portion of the heat dissipation member 6 other than the aforementioned part is disposed along the side surfaces of the semiconductor chip 2 and is partially in contact with the side surfaces of the semiconductor chip 2, similarly to in the semiconductor device 1.

In this case, a groove 31′ is formed in the wiring board portion 3, instead of the groove 31. The groove 31′ is formed to have such a depth that the heat dissipation member 6 is embedded and sunk (namely, the heat dissipation member 6 is entirely embedded) in the groove 31′, at its portion positioned beneath the semiconductor chip 2. Further, the groove 31′ is formed to have such a depth that the heat dissipation member 6 is partially protruded from the groove 31′ (such a depth that the heat dissipation member 6 can be partially in contact with the side surfaces of the semiconductor chip 2), at its portion along the side surfaces of the semiconductor chip 2.

In this case, similarly to in the semiconductor device 1, one end portion of the heat dissipation member 6 is connected to one communication path 20, and the other end portion of the heat dissipation member 6 is connected to the other communication path 20.

By disposing a part of the heat dissipation member 6 beneath the semiconductor chip 2 as described above, it is possible to dissipate heat beneath the semiconductor chip 2, thereby improving the efficiency of cooling of the semiconductor chip 2.

Furthermore, by forming the heat dissipation member 6 such that it is folded back beneath the semiconductor chip 2, it is possible to increase the efficiency of heat dissipation from the semiconductor chip 2 to the heat dissipation member 6, which can also improve the cooling efficiency.

### 1-2. Example of Method for Manufacturing Semiconductor Device

With reference to FIG. 5, there will be described an example of a method for manufacturing the semiconductor device 1.

First, the groove 31 is formed in the wiring board portion 3 through counterbore processing using a router bit or the like (see FIG. 5A). As can be understood from the above description, the groove 31 is formed at a position around the position at which the semiconductor chip 2 is mounted, in the front surface Sf of the wiring board portion 3.

Further, in the process illustrated in FIG. 5A, the grooves 32 for disposing parts 20a of the communication paths 20 therein are also formed in the wiring board portion 3.

Incidentally, in manufacturing the semiconductor device 1′ described with reference to FIGS. 3 and 4, the above-described groove 31′ is formed instead of the groove 31 in the process of FIG. 5A.

Next, the electronic components 7 are mounted on the back surface Sb of the wiring board portion 3 and, thereafter, the semiconductor chip 2 is mounted on the front surface Sf of the wiring board portion 3 (see FIG. 5B). The semiconductor chip 2 is bonded, through the chip adhesive 10, to the front surface Sf of the wiring board portion 3, at a predetermined position inside the groove 31.

Subsequently, the heat dissipation member 6 as a heat pipe is disposed and bonded, and wire bonding is performed through the bonding wires W (see FIG. 5C). Specifically, the thermally conductive resin 15 including a thermosetting resin, for example, is applied to the heat dissipation member 6 disposed in the groove 31, and the thermally conductive resin 15 is thermally cured. Then, terminals formed on the semiconductor chip 2 and the terminals Tb formed on the front surface Sf of the wiring board portion 3 are connected to each other through the bonding wires W, thereby wire-bonding the semiconductor chip 2 to the wiring board portion 3.

Further, In the present example, after the wire bonding, a process for forming the communication paths 20 is performed. At this time, the parts 20a of the communication paths 20 are inserted into the grooves 32. There are the two parts 20a corresponding to one end portion and the other end portion of the heat dissipation member 6. In the present example, the one end portion of the heat dissipation member 6 is connected to one of the parts 20a, and the other end portion of the heat dissipation member 6 is connected to the other one of the parts 20a, in such a way as to maintain the heat pipe structure.

Subsequently, the frame portion 4 as a molded component including a mold resin, for example, is attached to the front surface Sf of the wiring board portion 3 (see FIG. 5D).

Then, the lid portion 5 as a transparent substrate is bonded to the frame portion 4, through the lid-portion adhesive 11 applied onto the frame portion 4, thereby sealing the space surrounded by the frame portion 4 on the front surface Sf of the wiring board portion 3 (see FIG. 5E).

As a result, the semiconductor device 1 described with reference to FIGS. 1 and 2 has been formed.

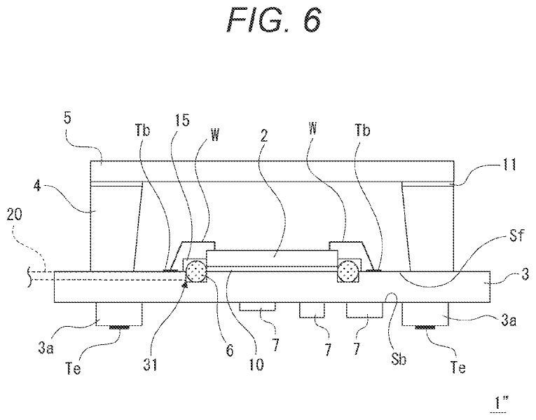

Incidentally, in the above description, there has been described an example where the communication paths 20 are arranged on the back surface Sb of the wiring board portion 3, but the communication paths 20 can also be arranged on the front surface Sf of the wiring board portion 3 as in a semiconductor device 1″ illustrated in FIG. 6.

FIG. 6 illustrates an example where there are formed grooves for embedding the communication paths 20 therein in the front surface Sf of the wiring board portion 3, and heat dissipation members forming the communication paths 20 are disposed in these grooves.

Here, in a case where a molded component is used as the frame portion 4, there may be a need for forming grooves in the frame portion 4 for passing the communication paths 20 therethrough, since the communication paths 20 cannot be accommodated in the grooves, depending on the depth of these grooves formed in the front surface Sf for the communication paths 20.

However, by forming the frame portion 4 on the wiring board portion 3 through transfer molding (a molding method which disposes a mold and pours a resin into the mold), instead of using a molded component as the frame portion 4, it is possible to eliminate the necessity of the process for forming the grooves in the frame portion 4.

Here, In the case where the communication paths 20 are formed in the front surface Sf of the wiring board portion 3 as illustrated in FIG. 6, it is possible to use a heat pipe having a portion forming the heat dissipation member 6 and portions forming the communication paths 20 which are integrated.

### 2. Second Embodiment

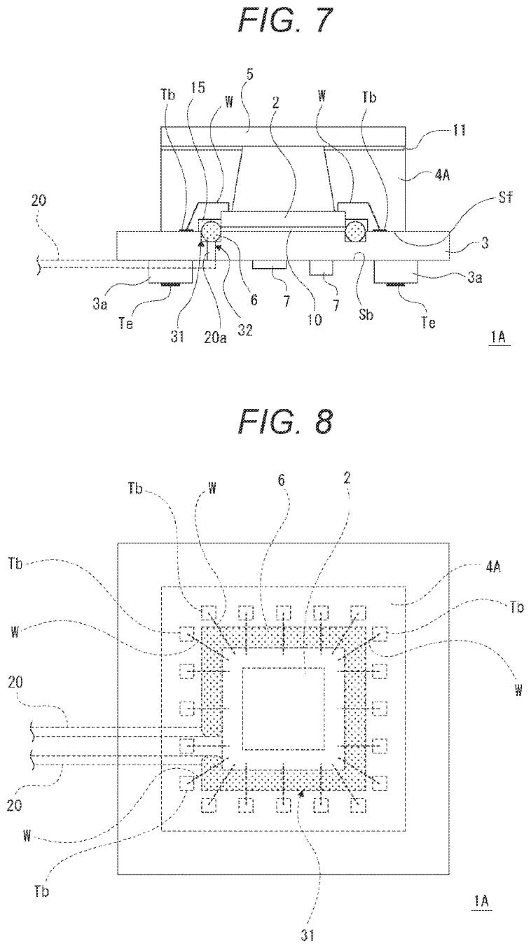

Subsequently, a semiconductor device 1A according to a second embodiment will be described with reference to FIGS. 7 and 8. FIGS. 7 and 8 are a schematic longitudinal cross-sectional view and a schematic plan view, respectively, of the semiconductor device 1A.

The semiconductor device 1A according to the second embodiment is different from the semiconductor device 1 according to the first embodiment in that the semiconductor device 1A is provided with a frame portion 4A, instead of the frame portion 4.

The frame portion 4A is different from the frame portion 4 in that the frame portion 4A is formed at such a position that it covers bonding wires W. In the present example, the frame portion 4A is formed so as to cover the entire bonding wires W. This causes the inner peripheral portion of the frame portion 4A to extend up to the outer edge portion of a semiconductor chip 2.

In the semiconductor device 1 according to the first embodiment, a gap is generated between the semiconductor chip 2 and the frame portion 4, which makes the size of the semiconductor device 1 larger by an amount corresponding to the gap. However, in the semiconductor device 1A according to the second embodiment, no gap is generated between the semiconductor chip 2 and the frame portion 4A, which enables downsizing the semiconductor device 1A.

In the present example, the frame portion 4A is formed on a wiring board portion 3 through transfer molding, for example, instead of attaching a molded component to the wiring board portion 3.

Further, in a case where a molded component is used as the frame portion 4A, it is desirable to preliminarily form grooves for accommodating the bonding wires W and the outer edge portion of the semiconductor chip 2 therein.

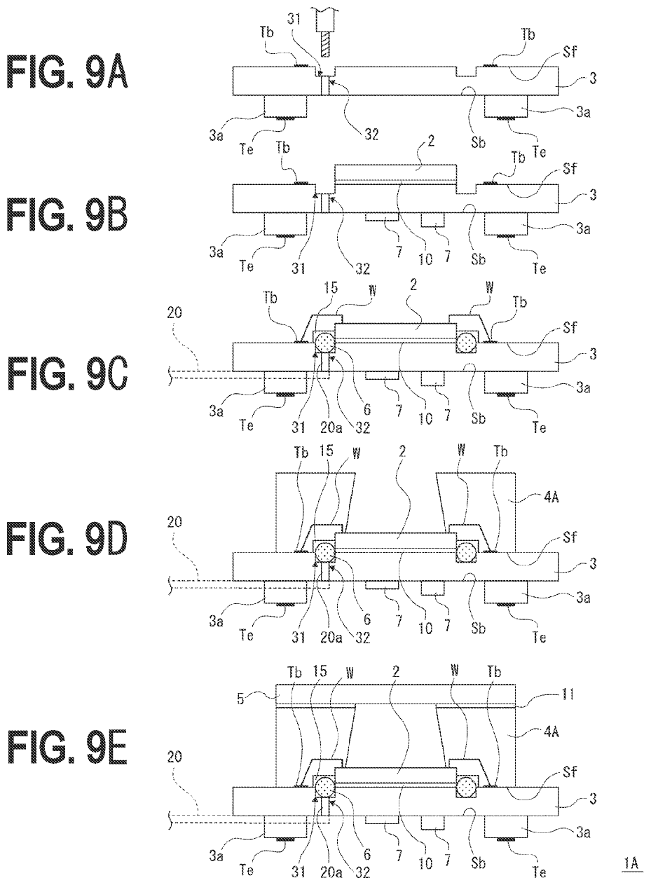

FIG. 9 is an explanatory view of an example of a method for manufacturing the semiconductor device 1A according to the second embodiment.

FIGS. 9A to 9C illustrate processes which are similar to those described with reference to FIGS. 5A to 5C, and these processes will not be described redundantly.

In this case, after the process of FIG. 9C (wire bonding and formation of communication paths 20), a process for forming the frame portion 4A illustrated in FIG. 9D is performed. For example, in the present example, the frame portion 4A is formed through transfer molding.

After the frame portion 4A is formed, a lid portion 5 as a transparent substrate is bonded to the frame portion 4A through a lid-portion adhesive 11 applied onto the frame portion 4A as illustrated in FIG. 9E, thereby sealing the space surrounded by the frame portion 4A.

Incidentally, here, there has been described an example where the communication paths 20 are arranged on the back surface Sb of the wiring board portion 3 similarly to in the semiconductor device 1A, but the communication paths 20 can also be arranged on the front surface Sf of the wiring board portion 3 as in the semiconductor device 1″ (FIG. 6).

Furthermore, in the second embodiment, similarly, it is also possible to adopt a configuration which disposes a part of a heat dissipation member 6 beneath the semiconductor chip 2 as in the semiconductor device 1′ (FIGS. 3 and 4).

### 3. Third Embodiment

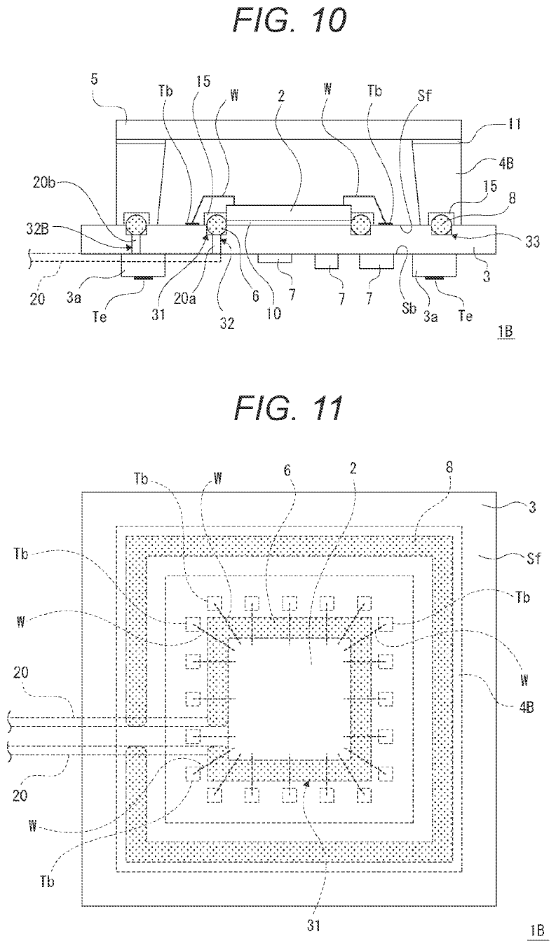

FIGS. 10 and 11 are a schematic longitudinal cross-sectional view and a schematic plan view, respectively, of a semiconductor device 1B according to a third embodiment.

In the semiconductor device 1B according to the third embodiment, in a frame portion forming a side wall portion of the semiconductor device 1, there is disposed a heat dissipation member different from a heat dissipation member 6 provided on the side surfaces of a semiconductor chip 2(an in-frame heat dissipation member 8 in the figure).

A wiring board portion 3 also functions as a heat dissipation path for heat generated in the semiconductor chip 2 and, therefore, heat from the semiconductor chip 2 can be also dissipated through the in-frame heat dissipation member 8.

The semiconductor device 1B is different from the semiconductor device 1 in that the semiconductor device 1B is provided with a frame portion 4B instead of the frame portion 4, and also is provided with the in-frame heat dissipation member 8 in the frame portion 4B. The in-frame heat dissipation member 8 is constituted by, for example, a heat pipe, similarly to the heat dissipation member 6.

In this case, in the wiring board portion 3, there is formed a groove 33 for embedding a part of the in-frame heat dissipation member 8 therein, in the region covered by the frame portion 4B. As illustrated in FIG. 11, in the present example, the in-frame heat dissipation member 8 is also formed so as to substantially go around the side portion of the semiconductor chip 2, similarly to the heat dissipation member 6, and the groove 33 is also formed so as to substantially go around the side portion of the semiconductor chip 2 similarly thereto.

A thermally conductive resin 15 is applied to the upper portion of the in-frame heat dissipation member 8, and the in-frame heat dissipation member 8 is bonded to the wiring board portion 3. This can increase the degree of thermal intimate contact between the in-frame heat dissipation member 8 and the wiring board portion 3.

The frame portion 4B is formed so as to cover the in-frame heat dissipation member 8 bonded to the wiring board portion 3 as described above.

The frame portion 4B can also be formed through transfer molding, for example, similarly to the aforementioned frame portion 4A. Alternatively, it is also possible to attach a molded component provided with a groove capable of accommodating the in-frame heat dissipation member 8 therein, to the wiring board portion 3.

In the present example, the heat dissipation member 6 and the in-frame heat dissipation member 8 share communication paths 20. Specifically, as illustrated in FIG. 11, the in-frame heat dissipation member 8 is connected, at its one end portion, to the communication path 20 connected to one end portion of the heat dissipation member 6, and, also, the in-frame heat dissipation member 8 is connected, at its other end portion, to the communication path 20 connected to the other end portion of the heat dissipation member 6.

Further, in the present example, the communication paths 20 are formed on the back surface Sb of the wiring board portion 3, similarly to in the semiconductor device 1. Therefore, in this case, in the wiring board portion 3, in addition to grooves 32 for connecting the heat dissipation member 6 and the communication paths 20 to each other, there are formed grooves 32B penetrating the wiring board portion 3 in the thickwise direction for connecting the in-frame heat dissipation member 8 and the communication paths 20 to each other (two grooves for one end portion and the other end portion). Parts 20b of the communication paths 20 (portions thereof different from the parts 20a described above) are inserted into the grooves 32B and connected to the in-frame heat dissipation member 8.

Incidentally, there has been described here an example where the in-frame heat dissipation member 8 shares the communication paths 20 with the heat dissipation member 6, in other words, they share the heat release portion. However, it is also possible to form a cooling circuit passing through the heat dissipation member 6, and a cooling circuit passing through the in-frame heat dissipation member 8 such that they are respective different loop circuits, and such that the heat dissipation member 6 and the in-frame heat dissipation member 8 are connected to respective different heat release portions.

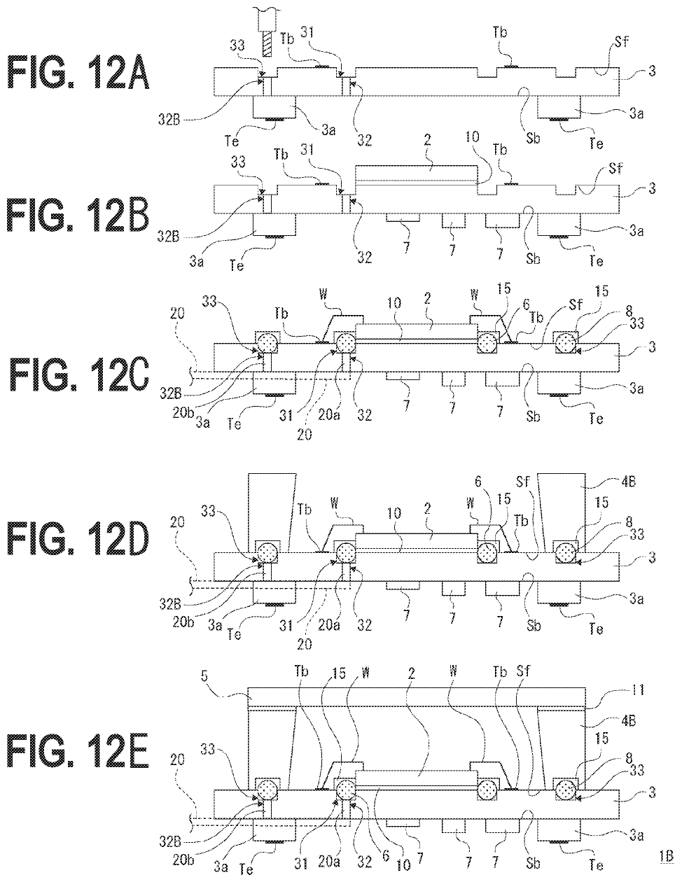

With reference to FIG. 12, there will be described an example of a method for manufacturing the semiconductor device 1B according to the third embodiment.

First, the groove 31, the grooves 32, the groove 33 and the grooves 32B are formed in the wiring board portion 3 through counterbore processing using a router bit or the like, for example (see FIG. 12A). Then, similarly to the process of FIG. 5B described above, a process for bonding the semiconductor chip 2 to the wiring board portion 3 is performed (see FIG. 12B).

Subsequently, in a process illustrated in FIG. 12C, the heat dissipation member 6 is disposed in the groove 31, and the in-frame heat dissipation member 8 is disposed in the groove 33. The thermally conductive resin 15 is applied to the heat dissipation member 6 and the in-frame heat dissipation member 8 and, thereafter, the thermally conductive resin 15 is thermally cured. Further, in the process illustrated in FIG. 12C, terminals on the semiconductor chip 2 and terminals Tb are wire-bonded through bonding wires W, and a process for forming the communication paths 20 is performed. Namely, in this case, the parts 20a inserted into the grooves 32 are connected to the heat dissipation member 6, and the parts 20b inserted into the grooves 32B are connected to the in-frame heat dissipation member 8, so that the heat dissipation member 6 and the in-frame heat dissipation member 8 are communicated with the communication paths 20.

Subsequently, in a process illustrated in FIG. 12D, the frame portion 4B covering the in-frame heat dissipation member 8 is formed on the front surface Sf of the wiring board portion 3. Then, in a process illustrated in FIG. 12E, a lid portion 5 as a transparent substrate is bonded to the frame portion 4B through a lid-portion adhesive 11 applied onto the frame portion 4B, thereby sealing the space surrounded by the frame portion 4B.

Incidentally, among the heat dissipation member 6 and the in-frame heat dissipation member 8, the heat dissipation member 6 may be omitted, and only the in-frame heat dissipation member 8 may be provided.

### 4. Fourth Embodiment

The fourth embodiment is an embodiment relating to a so-called caviless structure (cavity-less structure).

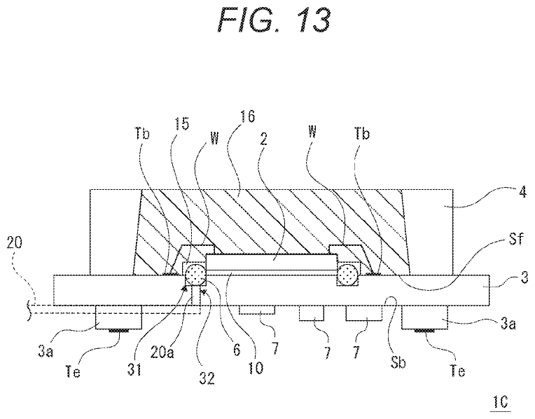

FIG. 13 is a schematic longitudinal cross-sectional view of a semiconductor device 1C as a first example of the fourth embodiment. The caviless structure does not include the transparent substrate as the lid portion 5, and seals the space surrounded by a frame portion by a transparent resin 16 added therein.

Specifically, the semiconductor device 1C in the first example is obtained by applying the caviless structure to the semiconductor device 1 according to the first embodiment. Further, the semiconductor device 1C is obtained by filling the space surrounded by the frame portion 4 with the transparent resin 16, instead of the lid portion 5 (and the lid-portion adhesive 11) omitted from the semiconductor device 1.

By adopting the caviless structure, a semiconductor chip 2 is covered with the transparent resin 16 in the space surrounded by the frame portion 4. In a case of adopting the cavity structure including the lid portion 5 which seals the space surrounded by the frame portion 4, the space surrounded by the frame portion 4 is made to be in a vacuum state or in a state of being filled with a predetermined gas such as nitrogen. However, by adopting the caviless structure including the transparent resin 16 added therein, it is possible to increase the thermal conductivity in the region surrounded by the frame portion 4, in comparison with the aforementioned case. Therefore, the semiconductor device 1C is contrived to efficiently conduct heat from the upper surface of the semiconductor chip 2 to the transparent resin 16, which enables efficiently conducting heat from the transparent resin 16 to a heat dissipation member 6, thereby improving the cooling efficiency.

Incidentally, FIG. 13 illustrates an example where communication paths 20 are formed on the back surface Sb of a wiring board portion 3 as an example where the caviless structure is adopted. However, in this case, the communication path 20 can be also formed on the front surface Sf of the wiring board portion 3.

Furthermore, in the case of adopting the caviless structure, similarly, it is possible to dispose a part of a heat dissipation member 6 beneath the semiconductor chip 2, as illustrated in FIGS. 3 and 4.

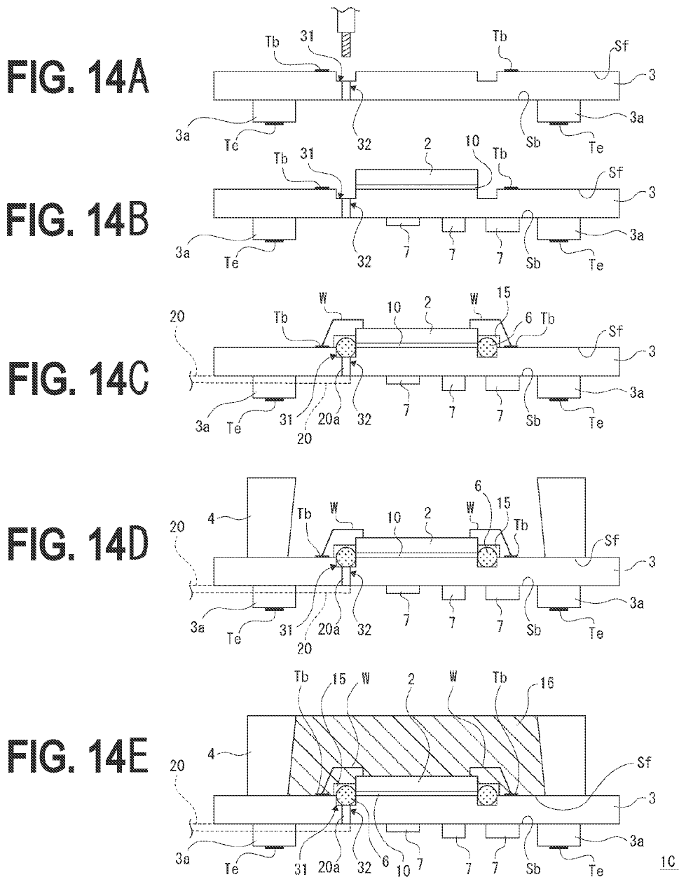

FIG. 14 is an explanatory view of an example of a method for manufacturing the semiconductor device 1C.

FIGS. 14A to 14D illustrate processes which are similar to those described with reference to FIGS. 5A to 5D, and these processes will not be described redundantly.

In this case, after the frame portion 4 is formed in the process of FIG. 14D, the space surrounded by the frame portion 4 is filled with the transparent resin 16 in a process of FIG. 14E.

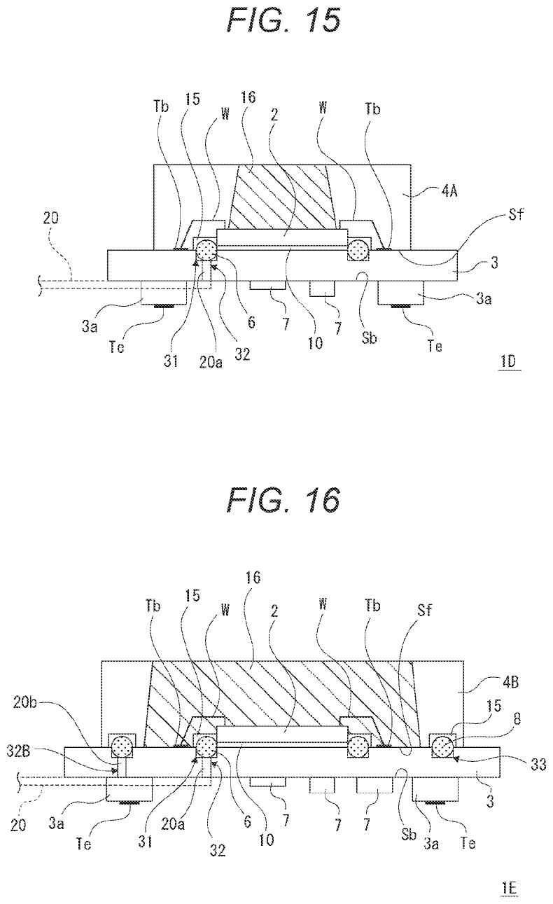

FIG. 15 is a schematic longitudinal cross-sectional view of a semiconductor device 1D as a second example of the fourth embodiment, and FIG. 16 is a schematic longitudinal cross-sectional view of a semiconductor device 1E as a third example of the fourth embodiment.

The semiconductor device 1D as the second example is obtained by applying the caviless structure to the semiconductor device 1A (FIGS. 7 and 8) according to the second embodiment. The semiconductor device 1E as the third example is obtained by applying the caviless structure to the semiconductor device 1B (FIG. 10, FIG. 11) according to the third embodiment.

Incidentally, as a method for manufacturing the semiconductor device 1D or the semiconductor device 1E, there is a need for only performing a process for filling the space surrounded by the frame portion 4A with the transparent resin 16 or a process for filling the space surrounded by the frame portion 4B with the transparent resin 16, instead of the process of FIG. 9E or the process of FIG. 12E.

### 5. Modification Examples

Here, the embodiments are not limited to the specific examples described above, and configurations as various modification examples can be adopted thereto.

For example, exemplified materials and shapes of the respective portions constituting the semiconductor devices are merely illustrative. It goes without saying that materials and shapes other than those exemplified above can be also adopted thereto.

Further, in the above description, as an example of the cooling circuit for heat generated in the semiconductor chip 2, there has been described a cooling circuit using a heat pipe. However, such a cooling circuit using a heat pipe is not limited to a loop-type cooling circuit exemplified above. For example, such a cooling circuit using a heat pipe may be a cooling circuit using a rod-shaped heat pipe disposed so as to be partially along any of the side surfaces of the semiconductor chip 2.

Further, In the above description, there has been described an example where the heat dissipation member 6 (and the in-frame heat dissipation member 8) is constituted by a heat pipe. However, as the heat dissipation member 6, it is also possible to employ a member other than a heat pipe, such as a tubular member adapted to move a refrigerant therein on the basis of the power of an actuator such as a motor, instead of the capillary phenomenon, for example.

Furthermore, in the above description, there has been described an example where the frame portion forming the side wall portion of the semiconductor device is separated from the wiring board portion. However, the frame portion may be integrated with the wiring board portion.

In the above description, there have been described examples where the present technology is applied to semiconductor devices as solid-state image pickup elements. However, the present technology can also be widely and preferably applied to other semiconductor devices than solid-state image pickup elements, such as semiconductor devices as light emitting devices including light emitting elements arranged in an array shape, such as Vertical Cavity Surface Emitting Lasers (VCSELs), and semiconductor device as distance measuring sensors including two-dimensionally arranged pixels for receiving light for distance measurement.

### 6. Conclusion of Embodiments

As described above, a semiconductor device (the same 1, 1′, 1″, 1A, 1B, 1C, 1D, 1E) according to an embodiment includes: a semiconductor chip (the same 2); and a wiring board portion (the same 3) having the semiconductor chip mounted thereon and having an external connection terminal (the same Te) for establishing electrical connection to the outside, the external connection terminal being formed on its back surface which is a surface opposite to its front surface which is a surface on which the semiconductor chip is mounted, in which the semiconductor chip is connected to a terminal formed on the front surface of the wiring board portion through a bonding wire (the same W) to be wire-bonded to the wiring board portion, and a heat dissipation member (the same 6) is disposed between the bonding wire and the wiring board portion.

According to the aforementioned configuration, the heat dissipation member is disposed near the semiconductor chip which forms a heat source. Further, in this case, the semiconductor device can be cooled by the heat dissipation member disposed in a dead space below the bonding wire.

Since the semiconductor device can be cooled by the heat dissipation member disposed in the dead space, it is possible to prevent the semiconductor device from having a larger size for the purpose of cooling.

Further, in the semiconductor device according to an embodiment, the heat dissipation member is at least partially in contact with a side surface of the semiconductor chip.

This improves the efficiency of heat conduction from the semiconductor chip to the heat dissipation member.

This can improve the cooling efficiency.

Further, in the semiconductor device according to an embodiment, the heat dissipation member is constituted by a heat pipe.

The heat pipe is enabled to circulate the refrigerant therein due to the capillary phenomenon, which eliminates the necessity of providing a drive portion for circulating the refrigerant, thereby enabling simplification of the configuration for cooling and reduction of the number of members required for cooling. This can reduce the cost of the semiconductor device.

Furthermore, the semiconductor device (the same 1A) according to an embodiment includes a frame portion (the same 4A) which protrudes from the wiring board portion in the same side as the side in which the semiconductor chip is mounted and which surrounds the side portion of the semiconductor chip, and the frame portion covers the bonding wire.

Thus, an inner peripheral portion of the frame portion extends up to an outer edge portion of the semiconductor chip.

Therefore, the semiconductor device can be downsized in comparison with a case of adopting a package of a type which positions the inner peripheral end of the frame portion outside the semiconductor chip.

Furthermore, in a case where the semiconductor device is formed to be a solid-state image pickup element, since the bonding wire is covered with the frame portion, it is possible to provide an effect of reducing flare caused by the bonding wire.

Further, the semiconductor device (the same 1B) according to an embodiment includes a frame portion (the same 4B) which protrudes from the wiring board portion in the same side as the side in which the semiconductor chip is mounted and which is provided outside the semiconductor chip to surround the side portion of the semiconductor chip, and, in the frame portion, there is disposed an in-frame heat dissipation member (the same 8) which is a heat dissipation member different from the heat dissipation member.

The wiring board portion also functions as a heat dissipation path for heat generated in the semiconductor chip and, therefore, heat from the semiconductor chip can be also dissipated through the in-frame heat dissipation member (by way of the wiring board portion and the frame portion).

This can improve the cooling efficiency.

Further, since the inside of the frame portion is also a dead space, the dead space can be effectively used as a heat dissipation path.

Furthermore, in the semiconductor device according to an embodiment, the heat dissipation member is at least partially embedded in a groove (the same 31, 31′) formed in the front surface of the wiring board portion.

Since the heat dissipation member is at least partially embedded in the groove formed in the wiring board portion as described above, it is possible to use the heat dissipation member having a larger cross-sectional area within the limited space below the bonding wire.

This can improve the efficiency of heat dissipation through the heat dissipation member, thereby improving the cooling efficiency.

Furthermore, in the semiconductor device according to an embodiment, the heat dissipation member is bonded to a side surface of the semiconductor chip through a thermally conductive resin (the same 15).

In a case where the heat dissipation member has a cross-sectional shape which is a shape other than a rectangular shape or the like, such as a case where a heat pipe is used as the heat dissipation member, it is difficult to bring the heat dissipation member evenly into intimate contact with the side surface of the semiconductor chip. For coping therewith, the heat dissipation member is bonded to the side surface of the semiconductor chip using the thermally conductive resin, in order to increase the degree of thermal intimate contact between the heat dissipation member and the semiconductor chip.

This enables efficiently guiding heat from the semiconductor chip to the heat dissipation member through the thermally conductive resin, thereby improving the cooling efficiency.

Further, by using a resin material thereas, it is possible to select a thermosetting resin as the thermally conductive resin, which enables streamlining the process for bonding the heat dissipation member and, also, securing the position of the heat dissipation member due to the bonding, thereby improving the stability of the cooling performance.

Further, in the semiconductor device according to an embodiment, the semiconductor chip is formed to have a substantially rectangular plate shape, and the heat dissipation member is in contact with all of the four side surfaces of the semiconductor chip.

This enables guiding heat generated in the semiconductor chip to the heat dissipation member, through all of the four side surfaces of the semiconductor chip.

This can improve the cooling efficiency.

Further, in the semiconductor device (the same 1″) according to an embodiment, communication paths (the same 20) from the heat dissipation member to a heat release portion are formed on the front surface of the wiring board portion.

This can eliminate the necessity of perforating the wiring board portion in connecting the heat dissipation member and the communication path to each other.

Therefore, it is possible to simplify the machining process for realizing the cooling function using the heat dissipation member, which enables reducing the manufacturing cost of the semiconductor device.

Further, in a case where electronic components other than the semiconductor chip are mounted on the back surface of the wiring board portion, it is necessary to form the communication paths in such a way as to avoid the portions where these electronic components are formed, which raises a concern about degradation of the degree of freedom in layout of the communication paths. However, by forming the communication paths on the front surface of the wiring board portion as described above, it is possible to circumvent the layout restriction that the electronic components be avoided, thereby increasing the degree of freedom in layout of the communication paths.

Further, in the semiconductor device according to an embodiment, the communication paths from the heat dissipation member to the heat release portion are formed on the back surface of the wiring board portion.

Therefore, in a case where a molded component as the frame portion is attached to the wiring board portion, it is possible to eliminate the necessity of machining the frame portion (forming a groove for passing the communication path therethrough).

Accordingly, for coping with a case where there is a difficulty in machining the frame portion, it is possible to avoid performing such a difficult machining. This can enhance the easiness of manufacturing of the semiconductor device, thereby reducing the manufacturing cost of the semiconductor device.

Furthermore, the semiconductor device (the same 1C, 1D, 1E) according to an embodiment includes a frame portion which protrudes from the wiring board portion in the same side as the side in which the semiconductor chip is mounted and which surrounds the side portion of the semiconductor chip, and a transparent resin (the same 16) with which the space surrounded by the frame portion is filled.

Namely, the semiconductor device has a so-called caviless structure (cavity-less structure) which does not employ a lid portion including a glass or the like for sealing the region surrounded by the frame portion, from above the frame portion. In this case, the semiconductor chip is covered with the transparent resin, in the space surrounded by the frame portion.

In a case of adopting a cavity structure which employs a lid portion for sealing the space surrounded by the frame portion, the space surrounded by the frame portion is made to be in a vacuum state or in a state of being filled with a predetermined gas such as nitrogen. However, by adopting the caviless structure which employs the transparent resin added therein, it is possible to increase the thermal conductivity in the region surrounded by the frame portion, in comparison with the aforementioned case. Therefore, the semiconductor device is contrived to efficiently conduct heat from the upper surface of the semiconductor chip to the transparent resin, which enables efficiently conducting heat from the transparent resin to the heat dissipation member, thereby improving the cooling efficiency.

Furthermore, due to the caviless structure, it is possible to eliminate the necessity of performing a process for sealing using a lid portion, which can reduce the manufacturing cost of the semiconductor device.

Further, the semiconductor device according to an embodiment is a semiconductor device as a solid-state image pickup element.

Therefore, it is possible to improve the efficiency of cooling the semiconductor device as a solid-state image pickup element.

A method for manufacturing a semiconductor device according to an embodiment is a method for manufacturing a semiconductor device including a semiconductor chip, and a wiring board portion having the semiconductor chip mounted thereon and having an external connection terminal for establishing electrical connection to the outside, the external connection terminal being formed on its back surface which is a surface opposite to its front surface which is a surface on which the semiconductor chip is mounted, and the semiconductor chip being connected to a terminal formed on the front surface of the wiring board portion through a bonding wire to be wire-bonded to the wiring board portion, in which the method includes at least a process for disposing a heat dissipation member between the bonding wire and the wiring board portion.

With this manufacturing method, it is possible to manufacture the semiconductor devices according to the aforementioned embodiments.

Note that the effects described in the present specification are merely illustrative and not restrictive, and the present technology may also have other effects.

### 7. Present Technology

Incidentally, the present technology can have the following configurations.
(1) A semiconductor device which includes:
a semiconductor chip; and
a wiring board portion having the semiconductor chip mounted thereon and having an external connection terminal for establishing electrical connection to the outside, the external connection terminal being formed on a back surface which is a surface opposite to a front surface which is a surface on which the semiconductor chip is mounted,
in which the semiconductor chip is connected to a terminal formed on the front surface of the wiring board portion through a bonding wire to be wire-bonded to the wiring board portion, and
a heat dissipation member is disposed between the bonding wire and the wiring board portion.
(2)
In the semiconductor device described in the aforementioned (1),
the heat dissipation member is at least partially in contact with a side surface of the semiconductor chip.
(3)
In the semiconductor device described in the aforementioned (1) or (2),
the heat dissipation member includes a heat pipe.
(4)
The semiconductor device described in any one of the aforementioned (1) to (3), including a frame portion which protrudes from the wiring board portion in the same side as the side in which the semiconductor chip is mounted and which surrounds the side portion of the semiconductor chip,
in which the frame portion covers the bonding wire.
(5)
The semiconductor device described in any one of the aforementioned (1) to (3) including a frame portion which protrudes from the wiring board portion in the same side as the side in which the semiconductor chip is mounted and which is provided outside the semiconductor chip to surround the side portion of the semiconductor chip,
in which in the frame portion, there is disposed an in-frame heat dissipation member which is a heat dissipation member different from the aforementioned heat dissipation member.
(6)
In the semiconductor device described in any one of the aforementioned (1) to (5),
the heat dissipation member is at least partially embedded in a groove formed in the front surface of the wiring board portion.
(7)
In the semiconductor device described in any one of the aforementioned (1) to (6),
the heat dissipation member is bonded to a side surface of the semiconductor chip through a thermally conductive resin.
(8)
In the semiconductor device described in any one of the aforementioned (1) to (7),
the semiconductor chip is formed to have a substantially rectangular plate shape, and
the heat dissipation member is in contact with all of the four side surfaces of the semiconductor chip.
(9)
In the semiconductor device described in any one of the aforementioned (1) to (8),
a communication path from the heat dissipation member to a heat release portion is formed on the front surface of the wiring board portion.
(10)
In the semiconductor device described in any one of the aforementioned (1) to (8),
a communication path from the heat dissipation member to a heat release portion is formed on the back surface of the wiring board portion.
(11)
The semiconductor device described in any one of the aforementioned (1) to (10) including:
a frame portion which protrudes from the wiring board portion in the same side as the side in which the semiconductor chip is mounted and which surrounds the side portion of the semiconductor chip; and
a transparent resin with which a space surrounded by the frame portion is filled.
(12)
The semiconductor device described in any one of the aforementioned (1) to (11)
which is formed to be a semiconductor device as a solid-state image pickup element.
(13)
A method for manufacturing a semiconductor device, the semiconductor device including:
a semiconductor chip; and
a wiring board portion having the semiconductor chip mounted thereon and having an external connection terminal for establishing electrical connection to the outside, the external connection terminal being formed on a back surface which is a surface opposite to a front surface which is a surface on which the semiconductor chip is mounted, and
the semiconductor chip being connected to a terminal formed on the front surface of the wiring board portion through a bonding wire to be wire-bonded to the wiring board portion,
in which the method includes at least a process for disposing a heat dissipation member between the bonding wire and the wiring board portion.

### REFERENCE SIGNS LIST

1, 1′, 1″, 1A, 1B, 1C, 1D, 1E Semiconductor device
2 Semiconductor chip
3 Wiring board portion
3a Protrusion
4, 4A, 4B Frame portion
5 Lid portion
6 Heat dissipation member
7 Electronic component
8 In-frame heat dissipation member
10 Chip adhesive
11 Lid-portion adhesive
15 Thermally conductive resin
16 Transparent resin
20 Communication path
20a, 20b Part
31, 31′, 32, 32B, 33 Groove
W Bonding wire
Te External connection terminal
Tb Terminal

What is claimed is:

1. A semiconductor device, comprising:
a semiconductor chip; and
a wiring board portion having the semiconductor chip mounted thereon and having an external connection terminal for establishing electrical connection to an outside, the external connection terminal being formed on a back surface which is a surface opposite to a front surface which is a surface on which the semiconductor chip is mounted,
wherein the semiconductor chip is connected to a terminal formed on the front surface of the wiring board portion through a bonding wire to be wire-bonded to the wiring board portion, and
a heat dissipation member is disposed between the bonding wire and the wiring board portion.

2. The semiconductor device according to claim 1,
wherein the heat dissipation member is at least partially in contact with a side surface of the semiconductor chip.

3. The semiconductor device according to claim 1,
wherein the heat dissipation member includes a heat pipe.

4. The semiconductor device according to claim 1, further comprising a frame portion which protrudes from the wiring board portion in the same side as a side in which the semiconductor chip is mounted and which surrounds a side portion of the semiconductor chip,
wherein the frame portion covers the bonding wire.

5. The semiconductor device according to claim 1, further comprising a frame portion which protrudes from the wiring board portion in the same side as a side in which the semiconductor chip is mounted and which is provided outside the semiconductor chip to surround a side portion of the semiconductor chip,
wherein in the frame portion, there is disposed an in-frame heat dissipation member which is a heat dissipation member different from the heat dissipation member.

6. The semiconductor device according to claim 1,
wherein the heat dissipation member is at least partially embedded in a groove formed in the front surface of the wiring board portion.

7. The semiconductor device according to claim 1,
wherein the heat dissipation member is bonded to a side surface of the semiconductor chip through a thermally conductive resin.

8. The semiconductor device according to claim 1, wherein
the semiconductor chip is formed to have a substantially rectangular plate shape, and
the heat dissipation member is in contact with all of four side surfaces of the semiconductor chip.

9. The semiconductor device according to claim 1,
wherein a communication path from the heat dissipation member to a heat release portion is formed on the front surface of the wiring board portion.

10. The semiconductor device according to claim 1,
wherein a communication path from the heat dissipation member to a heat release portion is formed on the back surface of the wiring board portion.

11. The semiconductor device according to claim 1, further comprising:
a frame portion which protrudes from the wiring board portion in the same side as a side in which the semiconductor chip is mounted and which surrounds a side portion of the semiconductor chip; and
a transparent resin with which a space surrounded by the frame portion is filled.

12. The semiconductor device according to claim 1
which is formed to be a semiconductor device as a solid-state image pickup element.

13. A method for manufacturing a semiconductor device, the semiconductor device including:
a semiconductor chip; and
a wiring board portion having the semiconductor chip mounted thereon and having an external connection terminal for establishing electrical connection to an outside, the external connection terminal being formed on a back surface which is a surface opposite to a front surface which is a surface on which the semiconductor chip is mounted, and
the semiconductor chip being connected to a terminal formed on the front surface of the wiring board portion through a bonding wire to be wire-bonded to the wiring board portion,
wherein the method comprises at least a process for disposing a heat dissipation member between the bonding wire and the wiring board portion.
